(19) United States
(12) Patent Application Publication
(10) Pub. No.: US 2013/0153864 A1
(43) Pub. Date: Jun. 20, 2013

(54) AMBIPOLAR INVERTER DEVICE STRUCTURE AND MANUFACTURING METHOD THEREOF

(71) Applicants: Chao-Feng Sung, Miaoli County (TW); Yen-Min Hsieh, Miaoli County (TW)

(72) Inventors: Chao-Feng Sung, Miaoli County (TW); Yen-Min Hsieh, Miaoli County (TW)

(73) Assignee: INDUSTRIAL TECHNOLOGY RESEARCH INSTITUTE, Hsinchu (TW)

(21) Appl. No.: 13/454,107

(22) Filed: Apr. 24, 2012

(30) Foreign Application Priority Data
Dec. 16, 2011 (TW) 100146905

(51) Int. Cl. H01L 51/30; H01L 51/40

(52) U.S. Cl. 257/40; 438/99; 257/E51.024; 257/E51.002

(57) ABSTRACT

An ambipolar inverter device suitable for use in an integrated circuit. An electron blocking layer and a hole blocking layer are respectively disposed at two sides of the ambipolar semiconductor layer, so that the operation of the inverter may be executed in a single device. In addition, the manufacturing method of the disclosure is simple, adopting only one patterning step, so as to effectively improve the performance of the ambipolar device.

### CROSS-REFERENCE TO RELATED APPLICATION

This application claims the priority benefit of Taiwan application serial no. 100146905, filed on Dec. 16, 2011. The entirety of the above-mentioned patent application is hereby incorporated by reference herein and made a part of this specification.

### TECHNICAL FIELD

The disclosure relates to a semiconductor device and a manufacturing method thereof.

### BACKGROUND

An inverter is a basic device used in an integrated circuit for inverting the phase of an input signal 180 degrees. Inverters are often used in analog circuits, such as audio amplifiers and clock oscillators. The inverter also is often used in electronic line design.

In general, there are two methods of manufacture for inverters used in integrated circuits. In the first method of manufacture is manufacturing a unipolar inverter. Two unipolar transistors (two PMOS or two NMOS) directly form a complementary logic circuit. The single-type PMOS or NMOS is used for direct construction, where the source/drain needs one kind of metal, and an active layer material needs a single-type (either P-type or N-type) of material. This method simplifies the process of manufacture, but has the disadvantage of easy signal distortion and high power consumption.

The second manner of manufacture, in which N-type and P-type organic thin film transistors are connected in series to form a complementary inverter circuit, is more commonly used. This manner has the advantage of low power consumption, high reliability and high noise tolerance. The disadvantage is that it is difficult to manufacture N-type and the P-type active layers on the same substrate, and also the necessity of performing individual patterning processes makes it difficult to prevent the material of each layer from being damaged.

No matter whether two unipolar transistors or two transistors with different polarities are used to form a typical CMOS inverter, two devices are required to make the combination, which occupies a large area and complicates the process.

### SUMMARY

In view of this, the disclosure is directed to an ambipolar inverter device structure, which is vertically disposed, thus dramatically decreasing the use area.

One of the embodiments provides an ambipolar inverter device structure, comprising a gate disposed on a substrate, two first electrodes disposed on the substrate, located at two sides of the gate and on a first plane, two second electrodes disposed on the substrate, located at two sides of the gate and on a second plane, an ambipolar semiconductor layer disposed between the first plane and the second plane, a first carrier blocking layer disposed between the ambipolar semiconductor layer and each of the first electrodes, a second carrier blocking layer disposed between the ambipolar semiconductor layer and each of the second electrodes and a dielectric layer disposed between the gate and each of the second electrodes.

Another embodiment provides a manufacturing method of an ambipolar inverter device structure, comprising forming two first electrodes on a substrate, forming a first carrier blocking material layer, an ambipolar semiconductor material layer and a second carrier blocking material layer on the substrate, so as to cover the first electrodes, patterning the first carrier blocking material layer, the ambipolar semiconductor material layer and the second carrier blocking material layer, so as to form a stack structure exposing a part of one of the first electrodes, forming two second electrodes on the substrate, in which one of the first electrodes is electrically connected to one of the second electrodes, forming a dielectric layer on the substrate, so as to cover the stack structure and the second electrodes, and forming a gate on the dielectric layer between the second electrodes.

Another embodiment presents a manufacturing method of an ambipolar inverter device structure comprising forming a gate on a substrate, forming a dielectric layer covering the gate on the substrate, forming two first electrodes on the dielectric layer, forming a first carrier blocking material layer, an ambipolar semiconductor material layer and a second carrier blocking material layer on the dielectric layer, to cover the first electrodes, patterning the first carrier blocking material layer, the ambipolar semiconductor material layer and the second carrier blocking material layer, to form a stack structure exposing a part of one of the first electrodes, and forming two second electrodes on the stack structure, in which one of the first electrodes is electrically connected to one of the second electrodes.

On the basis of the above description, an electron blocking layer and a hole blocking layer are respectively disposed at two sides of the ambipolar semiconductor layer and four contacts are arranged, so that the operation of the inverter may be executed in a single device, which dramatically improves a current on/off ratio, and moreover, no obvious current is generated during the operation in a low electric field. In addition, the manufacturing method of the disclosure is simple, and a semiconductor layer used by an N-type device and a P-type device at the same time may be defined by adopting only one patterning step, which reduces patterning processes many times on the semiconductor materials in the prior art, so as to effectively improve the performance of the ambipolar device.

### BRIEF DESCRIPTION OF THE DRAWINGS

FIG. 1A to FIG. 1D are schematic cross-sectional views of a manufacturing method of an ambipolar inverter device structure according to a first embodiment of the disclosure.

FIG. 1D-1 is a schematic cross-sectional view of the ambipolar inverter device structure.

FIG. 2A to FIG. 2B are schematic cross-sectional views of a manufacturing method of an ambipolar inverter device structure according to a second embodiment of the disclosure.

FIG. 2B-1 is a schematic cross-sectional view of the ambipolar inverter device structure.

FIG. 2B-2 is another schematic cross-sectional view of the ambipolar inverter device structure.

FIG. 3 is a Vᵢₙ-Vₒᵤₜ curve of an inverter device according to Example 1.

Common reference numerals are used throughout the drawings and the detailed description to indicate the same elements. The present invention will be more apparent from the following detailed description taken in conjunction with the accompanying drawings.

### DETAILED DESCRIPTION

### First Embodiment

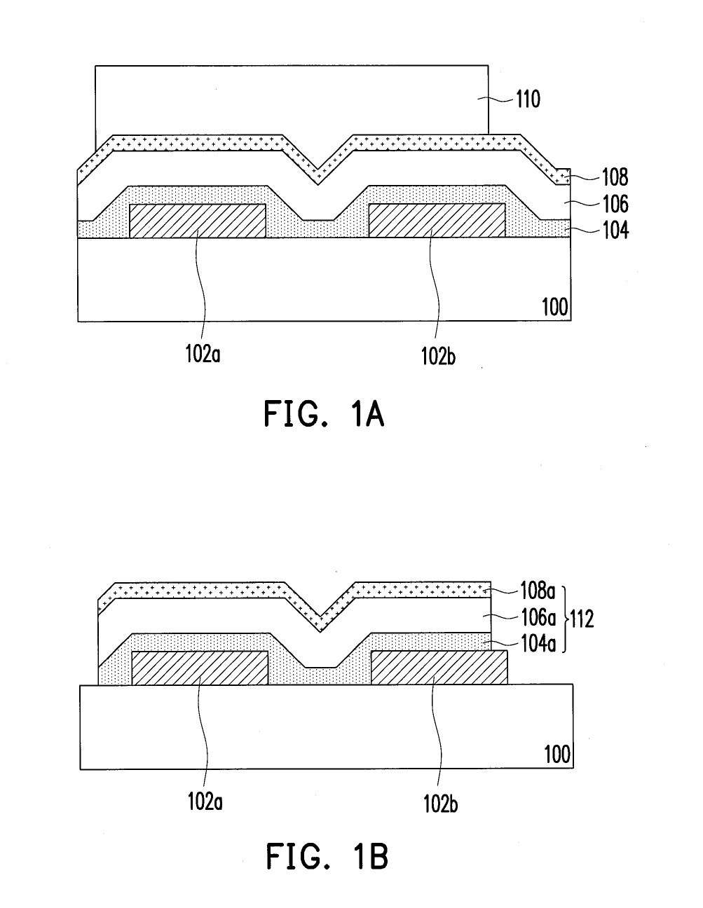

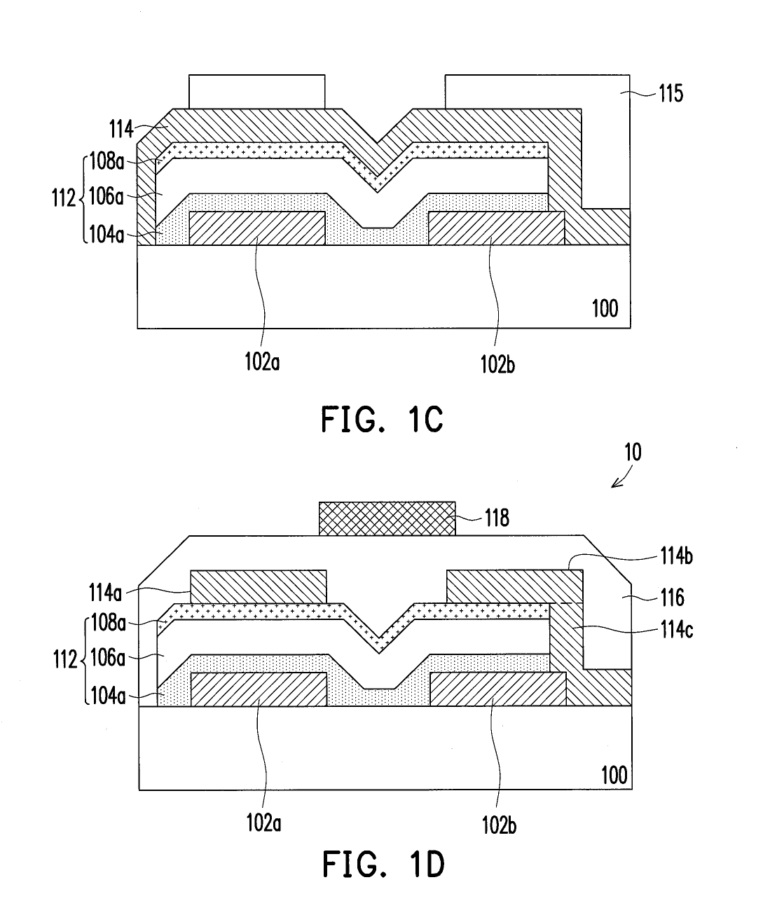

Referring to FIG. 1A, a schematic cross-sectional view of a manufacturing method of an ambipolar inverter device structure according to a first embodiment of the disclosure is shown. An electrode 102a and an electrode 102b separated from each other are formed on a substrate 100. The substrate 100 may be a rigid substrate or a flexible substrate. The material of the rigid substrate can be, but is not limited to, glass, quartz or silicon wafer. The material of the flexible substrate can be, but is not limited to, acrylic, metal foil or paper. A method for forming the electrode 102a and the electrode 102b includes forming an electrode layer (not shown) on the substrate 100, and then patterning the electrode layer through lithographic and etching processes to form the electrodes. The material of the electrode layer can be, but is not limited to, gold, silver, copper, aluminum, molybdenum, chromium or an alloy thereof. The method for forming the electrode layer includes performing a physical vapor deposition process. In another embodiment, the electrode 102a and the electrode 102b may be directly formed on the substrate 100 by using a conductive link printing method or a suitable transfer technology.

A carrier blocking material layer 104, an ambipolar semiconductor material layer 106, and a carrier blocking material layer 108 are formed on the substrate 100, so as to cover the electrodes 102a and 102b. A patterned photoresist layer 110 is formed on the carrier blocking material layer 108.

The carrier blocking material layers 104 and 108 may be respectively an electron blocking material layer and a hole blocking material layer, or a hole blocking material layer and an electron blocking material layer. When the carrier blocking material layer 104 or 108 is an electron blocking material layer, the electron blocking material layer may either be made of an inorganic material or an organic material. The inorganic material can be, but is not limited to, WO₃, V₂O₅, or MoO₃. The organic material can be, but is not limited to, 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq). When the carrier blocking material layer 104 or 108 is a hole blocking material layer, the hole blocking material layer may be made of either an inorganic material or an organic material. The inorganic material can be, but is not limited to, LiF, CsF, or TiO₂. The organic material can be, but is not limited to, 2,9-dimethyl-4,7-diphenyl-1,10-phenanthroline (BCP).

The material of the ambipolar semiconductor in the disclosure refers to a material with balanced hole property and electron property. In an embodiment, the ambipolar semiconductor material layer 106 is formed by stacking an N-type organic semiconductor material and a P-type organic semiconductor material. The N-type organic semiconductor material can be, but is not limited to, N,N′-ditridecyl-3,4,9,10-perylene tetracarboxylic diimide (PTCDI-C13), C₆₀, or [6,6]-phenyl-C61-butyric acid methyl ester (PCBM). The P-type organic semiconductor material can be, but is not limited to, pentacene, or poly(3-hexylthiophene) (P3HT). The N-type organic semiconductor material and the P-type organic semiconductor material are respectively formed through, for example, a vapor deposition method. In another embodiment, the ambipolar semiconductor material layer 106 is formed by mixing an N-type organic semiconductor material with a P-type organic semiconductor material. The N-type organic semiconductor material is mixed with the P-type organic semiconductor material in a solution process or a coevaporation method to form the ambipolar semiconductor material layer 106. In still another embodiment, the ambipolar semiconductor material layer 106 is made of an organic semiconductor material with an ambipolar property. The organic semiconductor material with the ambipolar property can be, but is not limited to, PDPP-TBT, or 8,9,10,11-tetrachloro-6,13-bis(triisopropylsilylethynyl)-1-azapentacene, and a forming method thereof includes a vapor deposition method or a solution process. In another embodiment, the ambipolar semiconductor material layer 106 is formed by stacking a N-type inorganic semiconductor material and a P-type inorganic semiconductor material, and a forming method thereof includes a vapor deposition method or a sputtering method. The N-type inorganic semiconductor material can be, but is not limited to, IGZO (InGaZnO₄), and the P-type inorganic semiconductor material can be, but is not limited to, SnO.

Referring to FIG. 1B, the carrier blocking material layer 104, the ambipolar semiconductor material layer 106 and the carrier blocking material layer 108 are patterned by using the patterned photoresist layer 110 as a mask, so as to form a stack structure 112 exposing a part of the electrode 102b. The stack structure 112 includes (from bottom to top) a carrier blocking layer 104a, an ambipolar semiconductor layer 106a and a carrier blocking layer 108a. The patterned photoresist layer 110 is removed.

Referring to FIG. 1C, an electrode layer 114 is formed on the substrate 100, so as to cover the stack structure 112 and an exposed surface of the electrode 102b. The material of the electrode layer 114 can be, but is not limited to, gold, sliver, copper, aluminum, molybdenum, chromium or an alloy thereof. The forming method of the electrode layer 114 includes performing a physical vapor deposition process, such as a vapor deposition method or a sputtering method. Then a patterned photoresist layer 115 is formed on the electrode layer 114.

Referring to FIG. 1D, a part of the electrode layer 114 is removed by using the patterned photoresist layer 115 as a mask, so as to form electrodes 114a and 114b respectively corresponding to the electrodes 102a and 102b on the substrate 100. The patterned photoresist layer 115 is removed. In addition, one of the electrodes 114a and 114b is electrically connected to one of the electrodes 102a and 102b.

In this embodiment, the electrodes at the same side are connected to each other. For example, the electrode 114b has an extending portion 114c, and the extending portion 114c is connected to the exposed surface of the electrode 102b along a side wall of the stack structure 112. In another embodiment, the electrodes at different sides may be connected to each other. For example, the electrode 114b could be electrically connected to the electrode 102a (or the electrode 114a could be electrically connected to the electrode 102b) through a lead (not shown).

A dielectric layer 116 is formed on the substrate 100, so as to cover the stack structure 112 and the electrodes 114a and 114b. A method for forming the dielectric layer 116 includes forming a dielectric material layer (not shown) on the substrate 100, and then patterning the dielectric material layer through lithographic and etching processes to form the dielectric layer. The material of the dielectric layer 116 includes an inorganic dielectric material or an organic dielectric material. The inorganic dielectric material can be, but is not limited to, silicon oxide or silicon nitride. The organic dielectric material can be, but is not limited to, polyvinyl pyrrolidone (PVP) or parylene. A method for forming the dielectric material layer includes performing a chemical vapor deposition method, a spin coating method, or a vapor deposition method.

A gate 118 is formed on the dielectric layer 116 between the electrode 114a and the electrode 114b, in which the dielectric layer 116 isolates the gate 118, the electrode 114a and the electrode 114b. A method for forming the gate 118 includes forming a gate material layer (not shown), and then patterning the gate material layer through lithographic and etching processes to form the gate. The material of the gate material layer can be, but is not limited to, gold, silver, copper, aluminum, molybdenum, chromium or an alloy thereof. A method for forming the gate material layer includes performing a physical vapor deposition process, such as a vapor deposition method or a sputtering method. In another embodiment, the gate 118 may be directly formed on the substrate 100 by using, for example, a conductive link printing method or a suitable transfer technology.

A protective layer (not shown) may be formed above the substrate 100, so as to cover the gate 118 and the dielectric layer 116.

Referring to FIG. 1D, the ambipolar inverter device structure 10 according to the first embodiment is an upper gate structure. The gate 118 is disposed on the substrate 100. The electrodes 102a and 102b are disposed on the substrate 100, and respectively located at two sides of the gate 118 and on a first plane. The electrodes 114a and 114b are disposed on the substrate 100, and respectively located at two sides of the gate 118 and on a second plane, in which one of the electrodes 102a and 102b is electrically connected to one of the electrodes 114a and 114b. In this embodiment, the electrode 102a is electrically connected to the electrode 114a. In addition, the electrodes 102a and 102b and the electrodes 114a and 114b are located below the gate 118, and the first plane is lower than the second plane. The ambipolar semiconductor layer 106a is disposed between the first plane and the second plane. The carrier blocking layer 104a is disposed between the ambipolar semiconductor layer 106a and each of the electrodes 102a and 102b. The carrier blocking layer 108a is disposed between the ambipolar semiconductor layer 106a and each of the electrodes 114a and 114b. The dielectric layer 116 is disposed between the gate 118 and each of the electrodes 114a and 114b.

It should be noted that, in the ambipolar inverter device structure 10 of this embodiment, an N-type device and a P-type device are vertically disposed, and share the ambipolar semiconductor layer 106a and the gate 118.

In an embodiment, the carrier blocking layer 104a is a hole blocking layer and the carrier blocking layer 108a is an electron blocking layer. In the lower structure, holes of the ambipolar semiconductor layer 106a are blocked from passing through and electrons are allowed to inject, so the lower structure is the N-type device. In the upper structure, electrons of the ambipolar semiconductor layer 106a are blocked from passing through and holes are allowed to inject, so the upper structure is the P-type device. In this way, an inverter device in which the N-type device is located below the P-type device is formed. For example, an input voltage Vᵢₙ is applied to the gate 118, an operation voltage V_{DD} is applied to the electrode 114b, a ground voltage V_{GND} is applied to the electrode 102a, and an output voltage Vₒᵤₜ is applied to the electrodes 102b and 114b, thus implementing the operation of the inverter device.

In another embodiment, the carrier blocking layer 104a can be the electron blocking layer and the carrier blocking layer 108a can be the hole blocking layer. In the lower structure, electrons of the ambipolar semiconductor layer 106a are blocked from passing through and holes are allowed to inject, so the lower structure is the a P-type device. In the upper structure, holes of the ambipolar semiconductor layer 106a are blocked from passing through and electrons are allowed to inject, so the upper structure is the N-type device. In this way, an inverter device in which the P-type device is located below the N-type device is formed.

The electron blocking layer and the hole blocking layer are respectively disposed at two sides of the ambipolar semiconductor layer, so that an electron property and a hole property may be respectively extracted from the ambipolar semiconductor layer, and moreover, the electron property and the hole property may be respectively used by an N-type device and a P-type device. In this way, a vertically disposed inverter device may be manufactured by using a single active layer and one patterning step. The method simplifies the process, so as to effectively improve the performance of the ambipolar device.

In an embodiment, the step of forming the carrier blocking layers 104a and 108a may also be omitted, and an ambipolar inverter device structure 10a shown in FIG. 1D-1 is obtained.

### Second Embodiment

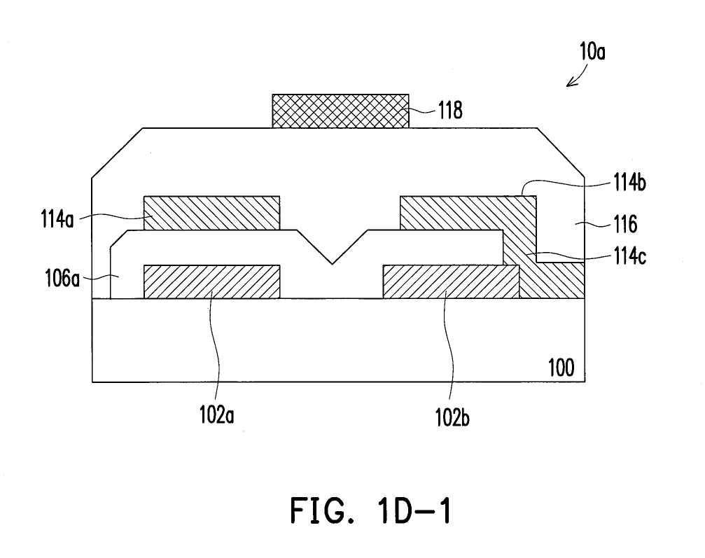

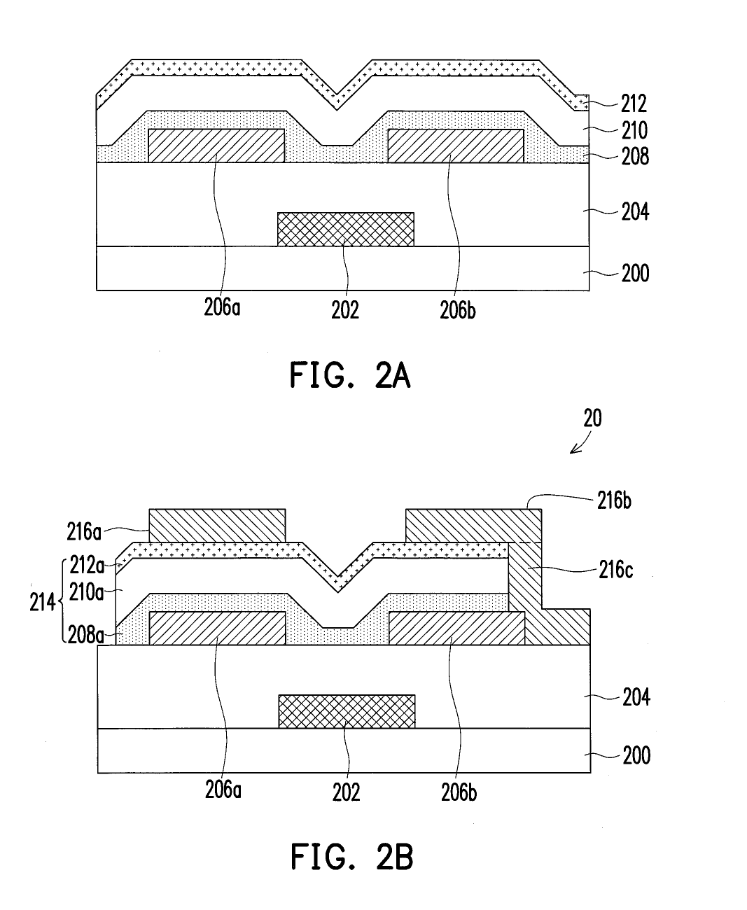

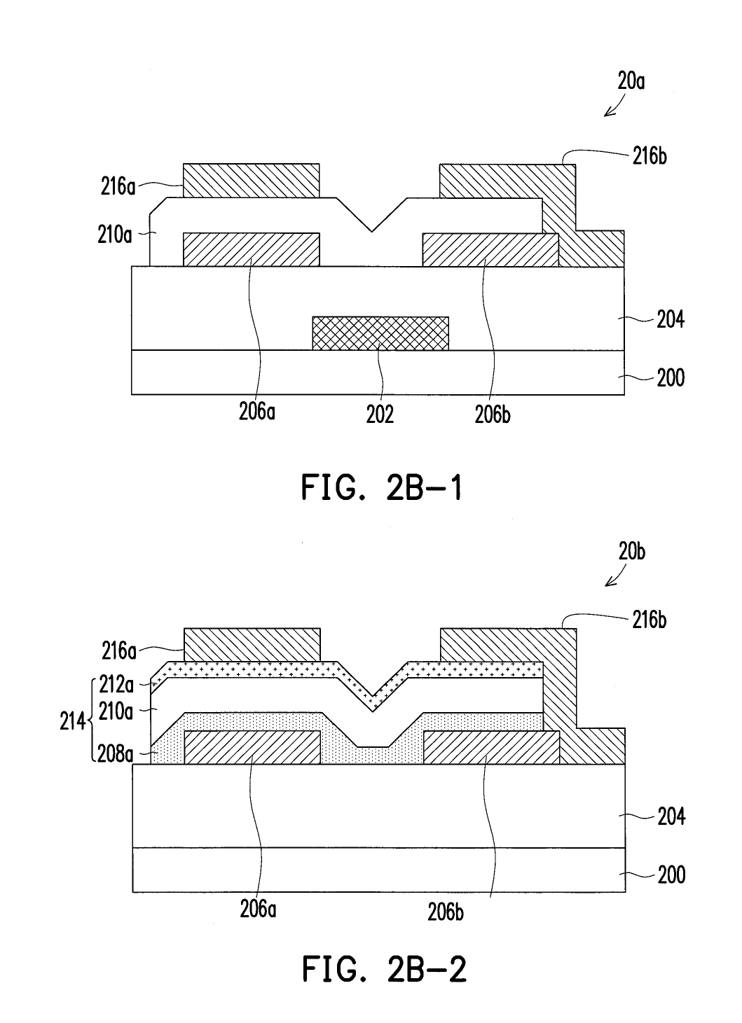

Referring to FIG. 2A, a gate 202 is formed on a substrate 200. A dielectric layer 204 covering the gate 202 is formed on the substrate 200. Electrodes 206a and 206b are formed on the dielectric layer 204. The materials and forming methods of the gate 202, the dielectric layer 204, the electrodes 206a and 206b in the second embodiment are similar to those of the gate 118, the dielectric layer 116, the electrodes 102a and 102b in the first embodiment.

A carrier blocking material layer 208, an ambipolar semiconductor material layer 210 and a carrier blocking material layer 212 are formed on the dielectric layer 104, so as to cover the electrodes 206a and 206b. The materials and forming methods of the carrier blocking material layer 208, the ambipolar semiconductor material layer 210 and the carrier blocking material layer 212 in the second embodiment are similar to those of the carrier blocking material layer 104, the ambipolar semiconductor material layer 106 and the carrier blocking material layer 108 in the first embodiment.

Referring to FIG. 2B, the carrier blocking material layer 208, the ambipolar semiconductor material layer 210 and the carrier blocking material layer 212 are patterned, so as to form a stack structure 214 exposing a part of the electrode 206b. The stack structure 214 includes (from bottom to top) a carrier blocking layer 208a, an ambipolar semiconductor layer 210a and a carrier blocking layer 212a.

Electrodes 216a and 216b corresponding to electrodes 206a and 206b are formed on the stack structure 214. One of the electrodes 216a and 216b is electrically connected to one of the electrodes 206a and 206b. In this embodiment, the electrodes at the same side are connected to each other. For example, the electrode 216b has an extending portion 216c, and the extending portion 216c is connected to an exposed surface of the electrode 206b along a side wall of the stack structure 214. In another embodiment, electrodes at different sides may be connected to each other. For example, the electrode 216b could be electrically connected to the electrode 206a (or the electrode 216a could be electrically connected to the electrode 206b) through a lead (not shown). The material and the forming method of the electrodes 216a and 216b in the second embodiment are similar to those of the electrodes 114a and 114b in the first embodiment.

Referring to FIG. 2B, the ambipolar inverter device structure 20 according to the second embodiment is a lower gate structure. The gate 202 is disposed on the substrate 200. The electrodes 216a and 216b are disposed on the substrate 200, and respectively located at two sides of the gate 202 and on a first plane. The electrodes 206a and 206b are disposed on the substrate 200, and respectively located at two sides of the gate 202 and on a second plane. A dielectric layer 204 is disposed between the gate 202 and each of the electrodes 206a and 206b. One of the electrodes 206a and 206b is electrically connected to one of the electrodes 216a and 216b. In this embodiment, the electrode 206a is electrically connected to the electrode 216a. In addition, the electrodes 206a and 206b and the electrodes 216a and 216b are located above the gate 202, and the first plane is higher than the second plane. The ambipolar semiconductor layer 210a is disposed between the first plane and the second plane. The carrier blocking layer 208a is disposed between the ambipolar semiconductor layer 210a and each of the electrodes 206a and 206b. The carrier blocking layer 212a is disposed between the ambipolar semiconductor layer 210a and each of the electrodes 216a and 216b.

It should be noted that, in the ambipolar inverter device structure 20 of this embodiment, an N-type device and a P-type device are vertically disposed, and share the ambipolar semiconductor layer 210a and the gate 202.

In an embodiment, when the carrier blocking layer 208a is a hole blocking layer and the carrier blocking layer 212a is an electron blocking layer, an inverter device in which the N-type device is located below the P-type device is formed. In another embodiment, when the carrier blocking layer 208a is an electron blocking layer and the carrier blocking layer 212a is a hole blocking layer, an inverter device in which the P-type device is located below the N-type device is formed.

In an embodiment, the step of forming the carrier blocking layers 208a and 212a may be omitted, and the ambipolar inverter device structure 20a shown in FIG. 2B-1 is obtained.

In addition, in the ambipolar inverter device structure 20 in FIG. 2B, that the gate 202 is formed on a glass substrate 200 is taken as an example, but the disclosure is not limited thereto. In another embodiment, when the substrate 200 is a silicon substrate, the step of forming the gate 202 may also be omitted, and the substrate 200 is used as a gate, as shown by an ambipolar inverter device structure 20b in FIG. 2B-2.

### Example 1

The substrate adopts a P-type silicon wafer (30˜60 Ω-cm, <100> crystal panel). Then, 200 nm silicon oxide as a dielectric layer is formed on the substrate. Two sliver electrodes are formed on the dielectric layer. A 500 Å BCP film as a hole blocking layer is evaporated on the dielectric layer and the sliver electrodes. Afterwards, the substrate is placed into a vacuum chamber and is evacuated to 2.5×10⁻⁶ ton, and by using BN crucible, PTCDI-C13 as an N-type organic semiconductor material and pentacene as a P-type organic semiconductor material are evaporated on the substrate at a rate of 0.5 to 1 Å/sec, so as to form an ambipolar semiconductor layer. At this time, a quartz oscillator is used to monitor the thickness of the film, and then a white-light interferometer is used to correct the thickness, so as to form a 450 Å PTCDI-C13 film and a 500 Å pentacene film. Then, A 500 Å m-MTDATA film as an electron blocking layer is evaporated on the ambipolar semiconductor layer. It should be noted that, the stack structure formed by the hole blocking layer, the ambipolar semiconductor layer and the electron blocking layer exposes a part of one sliver electrode. Two gold electrodes are formed on the electron blocking layer, and one of the gold electrodes is electrically connected to the exposed surface of the sliver electrode. Thus, the manufacturing of an inverter device in which the N-type device is located below the P-type device according to Example 1 is completed, as shown in FIG. 2B-2. The channel length of the device is 200 μm, and the channel width thereof is 2,000 μm.

The LUMO of the pentacene film and the PTCDI film is about 3.2 eV to 3.4 eV, and a work function of gold is about 5.1 eV, so an m-MTDATA film with the LUMO of 1.9 eV may effectively block the transmission of electrons and is suitable to serve as an electron blocking layer. In addition, the HOMO of the pentacene film and the PTCDI film is about 5.0 eV to 5.4 eV, and a work function of sliver is about 4.26 eV, so a BCP film with the HOMO of 6.7 eV may effectively block the transmission of holes and is suitable to serve as a hole blocking layer.

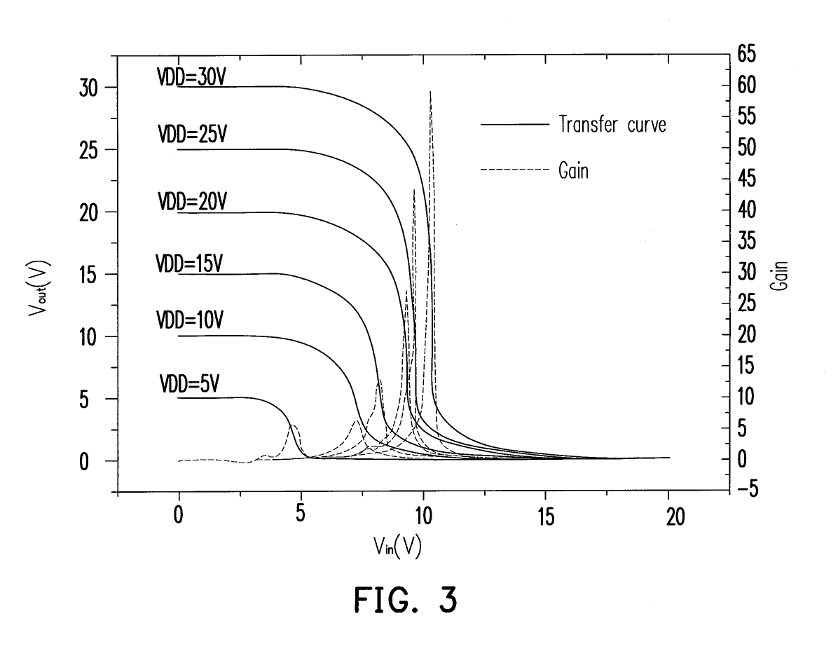

FIG. 3 is a Vᵢₙ-Vₒᵤₜ curve of an inverter device according to Example 1. As shown in FIG. 3, Vᵢₙ sweeps from 0 V to 20 V, V_{DD} sweeps from 5 V to 30 V, and the inverter device obtains a desirable transfer curve. When Vᵢₙ is less than V_{Tn}, a property curve of the inverter shows a horizontal line, which indicates that the voltage Vₒᵤₜ is stabilized at a V_{DD} level. When Vᵢₙ>>V_{Tn}, V_{DD}−Vᵢₙ≈|V_{Tp}|, the property curve shows a horizontal line, which indicates that the voltage Vₒᵤₜ is stabilized at a low voltage level. In addition, when Vᵢₙ˜V_{DD}/2>V_{Tn}, the property curve shows a vertical line, so the voltage Vₒᵤₜ may be dropped from V_{DD} to a low voltage in an instant. Finally, a gain equal to 59.79 is calculated according to the following equation (1). In such manner, the property of the COMS inverter is relatively close to an ideal device.

$$g = - \frac{d {V}_{out}}{d {V}_{in}} . \qquad ( 1 )$$

The electron blocking layer and the hole blocking layer are respectively disposed at two sides of the ambipolar semiconductor layer, so that an electron property and a hole property may be respectively extracted from the ambipolar semiconductor layer. Moreover, the electron property and the hole property may be respectively used by the N-type device and the P-type device. The ambipolar inverter device structure with four contacts of the disclosure may dramatically improve a current on/off ratio, and no obvious current is generated during the operation in a low electric field, thus widening the application range of the ambipolar inverter device structure.

In addition, the method of the disclosure may manufacture a vertically disposed inverter device by adopting a single active layer and one patterning step. Therefore, the method of the disclosure may simplify the process, and reduce the influence of the patterning process on the semiconductor material, so as to effectively improve the performance of the ambipolar device.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. An ambipolar inverter device structure, comprising:
a gate, disposed on a substrate;
two first electrodes, disposed on the substrate, and respectively located at two sides of the gate and on a first plane;
two second electrodes, disposed on the substrate, and respectively located at two sides of the gate and on a second plane, wherein one of the first electrodes is electrically connected to one of the second electrodes;
an ambipolar semiconductor layer, disposed between the first plane and the second plane;
a first carrier blocking layer, disposed between the ambipolar semiconductor layer and each of the first electrodes;
a second carrier blocking layer, disposed between the ambipolar semiconductor layer and each of the second electrodes; and
a dielectric layer, disposed between the gate and each of the second electrodes.

2. The ambipolar inverter device structure according to claim 1, wherein the first electrodes and the second electrodes are located below the gate.

3. The ambipolar inverter device structure according to claim 2, wherein the first plane is lower than the second plane.

4. The ambipolar inverter device structure according to claim 1, wherein the first electrodes and the second electrodes are located above the gate.

5. The ambipolar inverter device structure according to claim 4, wherein the first plane is higher than the second plane.

6. The ambipolar inverter device structure according to claim 1, wherein the ambipolar semiconductor layer is formed by stacking an N-type organic semiconductor material and a P-type organic semiconductor material.

7. The ambipolar inverter device structure according to claim 1, wherein the ambipolar semiconductor layer is formed by mixing an N-type organic semiconductor material with a P-type organic semiconductor material.

8. The ambipolar inverter device structure according to claim 1, wherein the ambipolar semiconductor layer is made of an organic semiconductor material with an ambipolar property.

9. The ambipolar inverter device structure according to claim 1, wherein the ambipolar semiconductor layer is formed by stacking an N-type inorganic semiconductor material and a P-type inorganic semiconductor material.

10. The ambipolar inverter device structure according to claim 1, wherein when the first carrier blocking layer is an electron blocking layer, the second carrier blocking layer is a hole blocking layer; or when the first carrier blocking layer is a hole blocking layer, the second carrier blocking layer is an electron blocking layer.

11. The ambipolar inverter device structure according to claim 1, wherein when the first carrier blocking layer or the second carrier blocking layer is an electron blocking layer, the electron blocking layer is made of an inorganic material or an organic material.

12. The ambipolar inverter device structure according to claim 11, wherein the inorganic material comprises WO₃, V₂O₅ or MoO₃.

13. The ambipolar inverter device structure according to claim 11, wherein the organic material comprises 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

14. The ambipolar inverter device structure according to claim 1, wherein when the first carrier blocking layer or the second carrier blocking layer is a hole blocking layer, the hole blocking layer is made of an inorganic material or an organic material.

15. The ambipolar inverter device structure according to claim 14, wherein the inorganic material comprises LiF, CsF or TiO₂.

16. The ambipolar inverter device structure according to claim 14, wherein the organic material comprises 2,9-dimethyl-4,7-diphenyl-1,10-phenanthroline (BCP).

17. A manufacturing method of an ambipolar inverter device structure, comprising:
forming two first electrodes on a substrate;
forming a first carrier blocking material layer, an ambipolar semiconductor material layer and a second carrier blocking material layer on the substrate, so as to cover the first electrodes;
patterning the first carrier blocking material layer, the ambipolar semiconductor material layer and the second carrier blocking material layer, so as to form a stack structure exposing a part of one of the first electrodes;
forming two second electrodes on the substrate, wherein one of the first electrodes is electrically connected to one of the second electrodes;
forming a dielectric layer on the substrate, so as to cover the stack structure and the second electrodes; and
forming a gate on the dielectric layer between the second electrodes.

18. The manufacturing method of an ambipolar inverter device structure according to claim 17, wherein a method for forming the second electrodes on the substrate comprises:
forming an electrode layer on the substrate, so as to cover the stack structure and an exposed surface of the first electrode;
forming a patterned photoresist layer on the electrode layer;
removing a part of the electrode layer by using the pattered photoresist layer as a mask, so as to form the second electrodes, wherein one of the second electrodes is connected to the exposed surface of the first electrode along a side wall of the stack structure; and
removing the pattered photoresist layer.

19. The manufacturing method of an ambipolar inverter device structure according to claim 17, wherein methods for forming the first carrier blocking material layer and the second carrier blocking material layer respectively comprise a vapor deposition method.

20. The manufacturing method of an ambipolar inverter device structure according to claim 17, wherein a method for forming the ambipolar semiconductor material layer comprises a vapor deposition method, a coevaporation method or a solution process.

21. The manufacturing method of an ambipolar inverter device structure according to claim 17, wherein the ambipolar semiconductor material layer is formed by stacking an N-type organic semiconductor material and a P-type organic semiconductor material.

22. The manufacturing method of an ambipolar inverter device structure according to claim 17, wherein the ambipolar semiconductor material layer is formed by mixing an N-type organic semiconductor material with a P-type organic semiconductor material.

23. The manufacturing method of an ambipolar inverter device structure according to claim 17, wherein the ambipolar semiconductor material layer is made of an organic semiconductor material with an ambipolar property.

24. The manufacturing method of an ambipolar inverter device structure according to claim 17, wherein the ambipolar semiconductor material layer is formed by stacking an N-type inorganic semiconductor material and a P-type inorganic semiconductor material.

25. The manufacturing method of an ambipolar inverter device structure according to claim 17, wherein when the first carrier blocking material layer is an electron blocking material layer, the second carrier blocking material layer is a hole blocking material layer; or when the first carrier blocking material layer is a hole blocking material layer, the second carrier blocking material layer is an electron blocking material layer.

26. The manufacturing method of an ambipolar inverter device structure according to claim 17, wherein when the first carrier blocking material layer or the second carrier blocking material layer is an electron blocking material layer, the electron blocking material layer is made of an inorganic material or an organic material.

27. The manufacturing method of an ambipolar inverter device structure according to claim 26, wherein the inorganic material comprises WO₃, V₂O₅ or MoO₃.

28. The manufacturing method of an ambipolar inverter device structure according to claim 26, wherein the organic material comprises 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

29. The manufacturing method of an ambipolar inverter device structure according to claim 17, wherein when the first carrier blocking material layer or the second carrier blocking material layer is a hole blocking material layer, the hole blocking material layer is made of an inorganic material or an organic material.

30. The manufacturing method of an ambipolar inverter device structure according to claim 29, wherein the inorganic material comprises LiF, CsF or TiO₂.

31. The manufacturing method of an ambipolar inverter device structure according to claim 29, wherein the organic material comprises 2,9-dimethyl-4,7-diphenyl-1,10-phenanthroline (BCP).

32. A manufacturing method of an ambipolar inverter device structure, comprising:
forming a gate on a substrate;
forming a dielectric layer covering the gate on the substrate;
forming two first electrodes on the dielectric layer;
forming a first carrier blocking material layer, an ambipolar semiconductor material layer and a second carrier blocking material layer on the dielectric layer, so as to cover the first electrodes;
patterning the first carrier blocking material layer, the ambipolar semiconductor material layer and the second carrier blocking material layer, so as to form a stack structure exposing a part of one of the first electrodes; and
forming two second electrodes on the stack structure, wherein one of the first electrodes is electrically connected to one of the second electrodes.

33. The manufacturing method of an ambipolar inverter device structure according to claim 32, wherein a method for forming the second electrodes on the substrate comprises:
forming an electrode layer on the substrate, so as to cover the stack structure and an exposed surface of the first electrode;
forming a patterned photoresist layer on the electrode layer;
removing a part of the electrode layer by using the pattered photoresist layer as a mask, so as to form the second electrodes, wherein one of the second electrodes is connected to the exposed surface of the first electrode along a side wall of the stack structure; and
removing the pattered photoresist layer.

34. The manufacturing method of an ambipolar inverter device structure according to claim 32, wherein methods for forming the first carrier blocking material layer and the second carrier blocking material layer respectively comprise a vapor deposition method.

35. The manufacturing method of an ambipolar inverter device structure according to claim 32, wherein a method for forming the ambipolar semiconductor material layer comprises a vapor deposition method, a coevaporation method or a solution process.

36. The manufacturing method of an ambipolar inverter device structure according to claim 32, wherein the ambipolar semiconductor material layer is formed by stacking an N-type organic semiconductor material and a P-type organic semiconductor material.

37. The manufacturing method of an ambipolar inverter device structure according to claim 32, wherein the ambipolar semiconductor material layer is formed by mixing an N-type organic semiconductor material with a P-type organic semiconductor material.

38. The manufacturing method of an ambipolar inverter device structure according to claim 32, wherein the ambipolar semiconductor material layer is made of an organic semiconductor material with an ambipolar property.

39. The manufacturing method of an ambipolar inverter device structure according to claim 32, wherein the ambipolar semiconductor material layer is formed by stacking an N-type inorganic semiconductor material and a P-type inorganic semiconductor material.

40. The manufacturing method of an ambipolar inverter device structure according to claim 32, wherein when the first carrier blocking material layer is an electron blocking material layer, the second carrier blocking material layer is a hole blocking material layer; or when the first carrier blocking material layer is a hole blocking material layer, the second carrier blocking material layer is an electron blocking material layer.

41. The manufacturing method of an ambipolar inverter device structure according to claim 32, wherein when the first carrier blocking material layer or the second carrier blocking material layer is an electron blocking material layer, the electron blocking material layer is made of an inorganic material or an organic material.

42. The manufacturing method of an ambipolar inverter device structure according to claim 41, wherein the inorganic material comprises WO₃, V₂O₅ or MoO₃.

43. The manufacturing method of an ambipolar inverter device structure according to claim 41, wherein the organic material comprises 4′,4″-tris(N-3-methylphenyl-N-phenylamino)triphenylamine (m-MTDATA) or bis(2-methyl-8-quinolinolato-N1,O8)-(1,1′-biphenyl-4-olato) aluminum (BALq).

44. The manufacturing method of an ambipolar inverter device structure according to claim 32, wherein when the first carrier blocking material layer or the second carrier blocking material layer is a hole blocking material layer, the hole blocking material layer is made of an inorganic material or an organic material.

45. The manufacturing method of an ambipolar inverter device structure according to claim 44, wherein the inorganic material comprises LiF, CsF or TiO₂.

46. The manufacturing method of an ambipolar inverter device structure according to claim 44, wherein the organic material comprises 2,9-dimethyl-4,7-diphenyl-1,10-phenanthroline (BCP).
